(19) United States
(12) Patent Application Publication
(10) Pub. No.: US 2025/0300669 A1
(43) Pub. Date: Sep. 25, 2025

(54) Analog-to-digital conversion circuit and time-interleaved analog-to-digital conversion circuit

(71) Applicant: REALTEK SEMICONDUCTOR CORPORATION, Hsinchu (TW)

(72) Inventors: WEI-CIAN HONG, Hsinchu (TW); AN-MING LEE, Hsinchu (TW)

(21) Appl. No.: 19/078,333

(22) Filed: Mar. 13, 2025

(30) Foreign Application Priority Data
Mar. 22, 2024 (TW) 113110909

(51) Int. Cl. H03M 1/50

(52) U.S. Cl. CPC H03M 1/50

(57) ABSTRACT

An analog-to-digital conversion circuit that converts an input signal into a digital signal includes a buffer circuit, a switch, an analog-to-digital converter (ADC), and a control circuit. The buffer circuit is configured to receive the input signal and generate an intermediate voltage. The switch is configured to sample the intermediate voltage according to an operating clock to generate a voltage. The ADC is configured to convert the voltage into the digital signal according to the operating clock and generate an indication signal. The control circuit is configured to adjust a duty cycle of the operating clock according to the indication signal and a reference clock. The indication signal indicates that the ADC has completed an analog-to-digital conversion operation.

### BACKGROUND OF THE INVENTION

### 1. Field of the Invention

The present invention generally relates to analog-to-digital conversion, and, more particularly, to an analog-to-digital conversion circuit and a time-interleaved analog-to-digital conversion circuit.

### 2. Description of Related Art

Reference is made to FIG. 1, which shows a schematic diagram of a conventional analog-to-digital converter (ADC) and its operating clock. The input signal Vin becomes the voltage Vin_s after passing through the buffer circuit 110 and the sampling switch SW. The ADC 120 converts the voltage Vin_s into the digital signal Dout. One of the functions of the buffer circuit 110 is to enhance the driving capability of the input signal Vin to drive the ADC 120. The buffer circuit 110 may be a voltage follower (also known as a unity gain buffer), for example, a source follower. The sampling switch SW and the ADC 120 operate according to the operating clock CLK. Tp is the period of the operating clock CLK (i.e., the operating frequency of the ADC 120 is 1/Tp), Ts is the sampling time of the sampling switch SW, and Tc is the conversion time of the ADC 120.

The disadvantage of the circuit in FIG. 1 is that the sampling time Ts and the conversion time Tc are fixed. When the ADC 120 completes the conversion early (i.e., generates the digital signal Dout early), the circuit in FIG. 1 becomes idle. However, the idle time is not utilized to enhance the performance of the circuit.

### SUMMARY OF THE INVENTION

In view of the issues of the prior art, an object of the present invention is to provide an analog-to-digital conversion circuit and a time-interleaved analog-to-digital conversion circuit, so as to make an improvement to the prior art.

According to one aspect of the present invention, an analog-to-digital conversion circuit is provided. The analog-to-digital conversion circuit is configured to convert an input signal into a digital signal and includes: a buffer circuit configured to receive the input signal and generate an intermediate voltage; a switch coupled to the buffer circuit and configured to sample the intermediate voltage according to an operating clock to generate a voltage; an analog-to-digital converter (ADC) coupled to the switch and configured to convert the voltage into the digital signal according to the operating clock and generate an indication signal; and a control circuit coupled to the switch and the ADC and configured to adjust a duty cycle of the operating clock according to the indication signal and a reference clock. The indication signal indicates that the ADC has completed an analog-to-digital conversion operation.

According to another aspect of the present invention, a time-interleaved analog-to-digital conversion circuit is provided. The time-interleaved analog-to-digital conversion circuit is configured to convert an input signal into a digital signal and includes: a first buffer circuit configured to receive the input signal and generate an intermediate voltage; a first switch coupled to the first buffer circuit and configured to sample the intermediate voltage according to a first operating clock to generate a first voltage; a second switch coupled to the first buffer circuit and configured to sample the intermediate voltage according to a second operating clock to generate a second voltage; a second buffer circuit coupled to the first switch; a third buffer circuit coupled to the second switch; a first analog-to-digital converter (ADC) coupled to the second buffer circuit and configured to operate according to a third operating clock and generate a first indication signal; a second ADC coupled to the second buffer circuit and configured to operate according to a fourth operating clock and generate a second indication signal; a third ADC coupled to the third buffer circuit and configured to operate according to a fifth operating clock and generate a third indication signal; a fourth ADC coupled to the third buffer circuit and configured to operate according to a sixth operating clock and generate a fourth indication signal; and a control circuit coupled to the first switch, the second switch, the first ADC, the second ADC, the third ADC, and the fourth ADC, and configured to adjust at least one of duty cycles of the first operating clock, the second operating clock, the third operating clock, the fourth operating clock, the fifth operating clock, and the sixth operating clock according to the first indication signal, the second indication signal, the third indication signal, the fourth indication signal, and a reference clock. The first indication signal, the second indication signal, the third indication signal, and the fourth indication signal respectively indicate that an analog-to-digital conversion operation of the first ADC, the second ADC, the third ADC, and the fourth ADC has been completed.

The technical means embodied in the embodiments of the present invention can solve at least one of the problems of the prior art. Therefore, compared to the prior art, the present invention can improve the performance of analog-to-digital conversion circuits.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 shows a schematic diagram of a conventional analog-to-digital converter (ADC) and its operating clock.

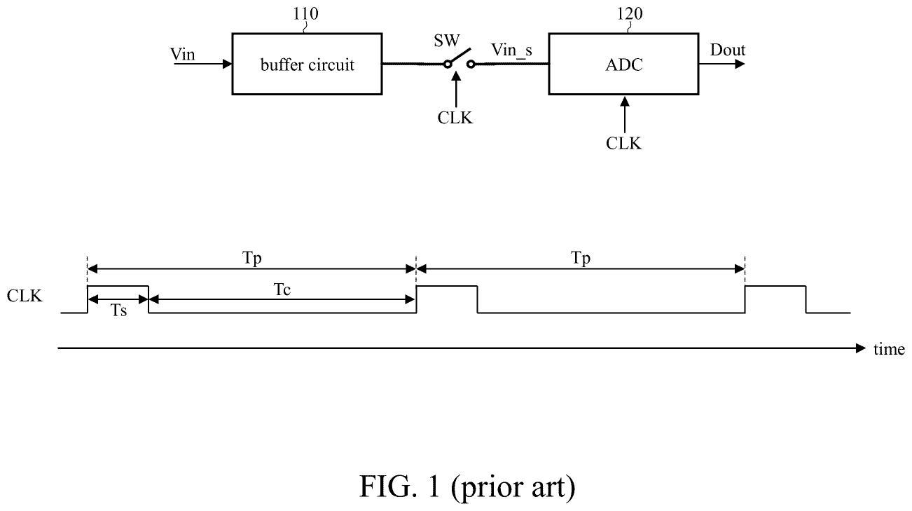

FIG. 2 is the functional block diagram of the analog-to-digital conversion circuit according to an embodiment of the present invention.

FIG. 3 is a functional block diagram of the control circuit according to an embodiment of the present invention.

FIG. 4 illustrates the waveforms of a clock adjustment according to an embodiment of the present invention.

FIG. 5 illustrates the waveforms of a clock adjustment according to another embodiment of the present invention.

FIG. 6 is the circuit diagram of the buffer circuit according to an embodiment of the present invention.

FIG. 7 is the circuit diagram of the buffer circuit according to another embodiment of the present invention.

FIG. 8A is a circuit diagram of the control circuit and the buffer circuit according to another embodiment of the present invention.

FIG. 8B is a circuit diagram of the delay unit.

FIG. 8C illustrates the internal circuit of the buffer circuit.

FIG. 9A is a functional block diagram of the time-interleaved ADC according to an embodiment of the present invention.

FIG. 9B illustrates the clocks corresponding to FIG. 9A.

FIG. 10A is a functional block diagram of the time-interleaved ADC according to another embodiment of the present invention.

FIG. 10B illustrates the clocks corresponding to FIG. 10A.

FIG. 11 is a functional block diagram of the control circuit according to another embodiment of the present invention.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes an analog-to-digital conversion circuit and a time-interleaved analog-to-digital conversion circuit. On account of that some or all elements of the analog-to-digital conversion circuit and the time-interleaved analog-to-digital conversion circuit could be known, the detail of such elements is omitted provided that such detail has little to do with the features of this disclosure, and that this omission nowhere dissatisfies the specification and enablement requirements. A person having ordinary skill in the art can choose components or steps equivalent to those described in this specification to carry out the present invention, which means that the scope of this invention is not limited to the embodiments in the specification.

In the following description, signals are active-high, which means that signals are active at high levels and inactive at low levels. This is for the purpose of explanation, not for limiting the scope of the invention. In other words, in an alternative implementation, signals can be active-low, which means that signals are active at low levels and inactive at high levels.

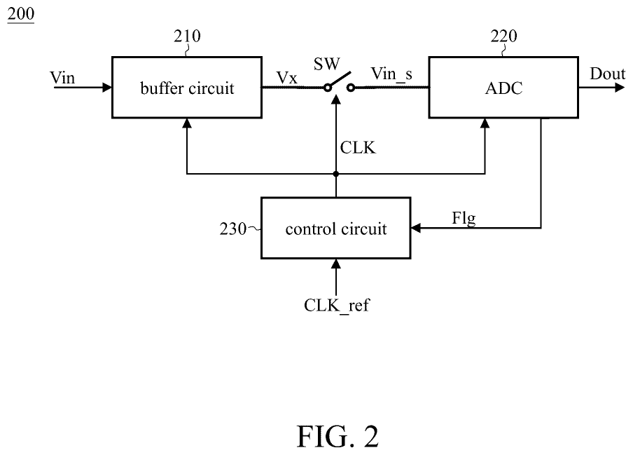

Reference is made to FIG. 2, which is a functional block diagram of an analog-to-digital conversion circuit according to an embodiment of the present invention. The analog-to-digital conversion circuit 200 includes a buffer circuit 210, an analog-to-digital converter (ADC) 220, and a control circuit 230, which are coupled to each other. The buffer circuit 210 generates an intermediate voltage Vx according to the input signal Vin. The sampling switch SW samples the intermediate voltage Vx according to the operating clock CLK to generate the voltage Vin_s. The ADC 220 converts the voltage Vin_s into a digital signal Dout according to the operating clock CLK, and generates an indication signal Flg after completing each analog-to-digital conversion (i.e., when all bits or one of the bits of the digital signal Dout is generated). The control circuit 230 generates the operating clock CLK based on the indication signal Flg and the reference clock CLK_ref. The buffer circuit 210 changes its internal current according to the operating clock CLK. When the current inside the buffer circuit 210 is greater, the bandwidth of the buffer circuit 210 is greater (i.e., the buffer circuit 210's ability to track the input signal Vin is stronger), but it consumes more power. On the contrary, when the current inside the buffer circuit 210 is smaller, the bandwidth of the buffer circuit 210 is smaller (i.e., the buffer circuit 210's ability to track the input signal Vin is weaker), but it is more power-efficient.

In some embodiments, when the buffer circuit 210 is embodied by a unity gain buffer (e.g., a source follower), the intermediate voltage Vx is substantially equal to the input signal Vin.

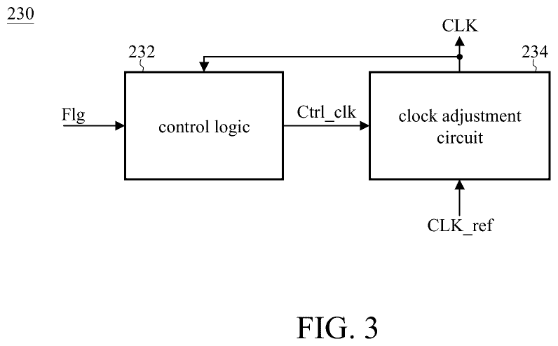

Reference is made to FIG. 3, which is a functional block diagram of the control circuit according to an embodiment of the present invention. The control circuit 230 includes a control logic 232 and a clock adjustment circuit 234, which are coupled to each other. The control logic 232 generates the clock adjustment signal Ctrl_clk based on the indication signal Flg and the operating clock CLK. The clock adjustment circuit 234 adjusts the reference clock CLK_ref according to the clock adjustment signal Ctrl_clk to generate the operating clock CLK. In some embodiments, the clock adjustment circuit 234 can be embodied by a phase interpolation circuit and/or a delay circuit.

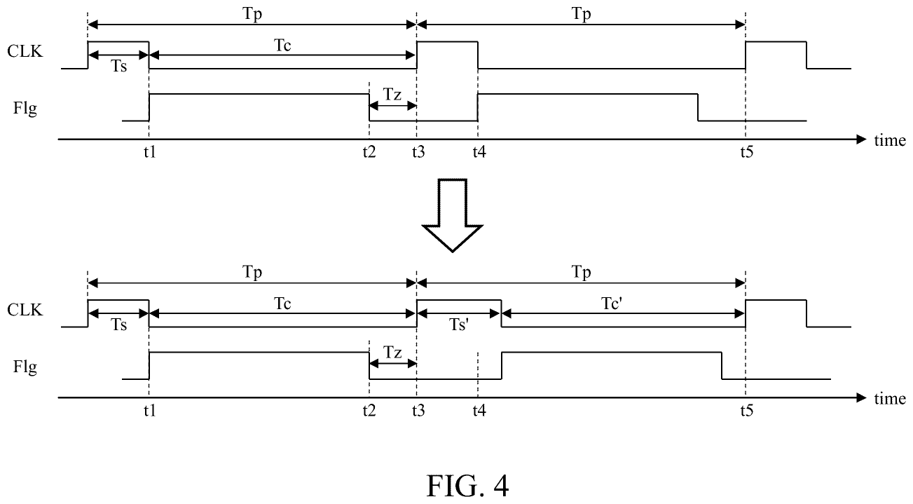

Reference is made to FIG. 4, which illustrates the waveforms of a clock adjustment according to an embodiment of the present invention (the upper part is the clock before adjustment, and the lower part is the clock after adjustment). Before the adjustment, the indication signal Flg transitions at the time point t2, meaning that the ADC 220 completes the analog-to-digital conversion (i.e., generates the digital signal Dout or one of the bits of the digital signal Dout). The time difference Tz between the time point t2 and the time point t3 indicates the early termination of the analog-to-digital conversion. The control logic 232 generates the clock adjustment signal Ctrl_clk by comparing or performing logical operations on the operating clock CLK and the indication signal Flg, and the clock adjustment circuit 234 adjusts the duty cycle of the operating clock CLK according to the clock adjustment signal Ctrl_clk. More specifically, in the example of FIG. 4, because the analog-to-digital conversion terminates early, the control logic 232 controls the clock adjustment circuit 234 to increase the duty cycle of the operating clock CLK (as a result, the sampling time Ts′>Ts, and the conversion time Tc′<Tc). As a result, in the next operating cycle, the sampling switch SW has a longer sampling time Ts', which can improve the linearity of the voltage Vin_s and the entire analog-to-digital conversion circuit 200.

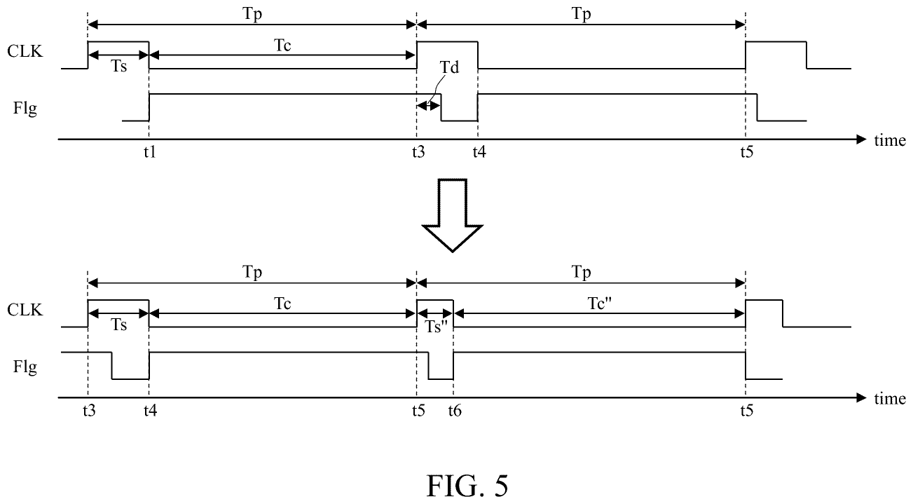

Reference is made to FIG. 5, which illustrates the waveforms of a clock adjustment according to another embodiment of the present invention (the upper part is the clock before adjustment, and the lower part is the clock after adjustment). Before adjustment, the indication signal Flg transitions between the time point t3 and the time point t4, meaning that the analog-to-digital conversion has exhausted the allowed conversion time Tc (the time difference Td represents the delay in the completion of the analog-to-digital conversion; thus, a total conversion time of Tc+Td is required). In the example of FIG. 5, because the analog-to-digital conversion requires a longer time, the control logic 232 controls the clock adjustment circuit 234 to reduce the duty cycle of the operating clock CLK (as a result, the sampling time Ts″<Ts, and the conversion time Tc″>Tc). Therefore, in the next operating cycle, the sampling switch SW has a longer conversion time Tc″, which can improve the accuracy of the entire analog-to-digital conversion circuit 200.

In addition to adjusting the duty cycle of the operating clock CLK, the analog-to-digital conversion circuit 200 of the present invention can also correspondingly adjust the buffer circuit 210.

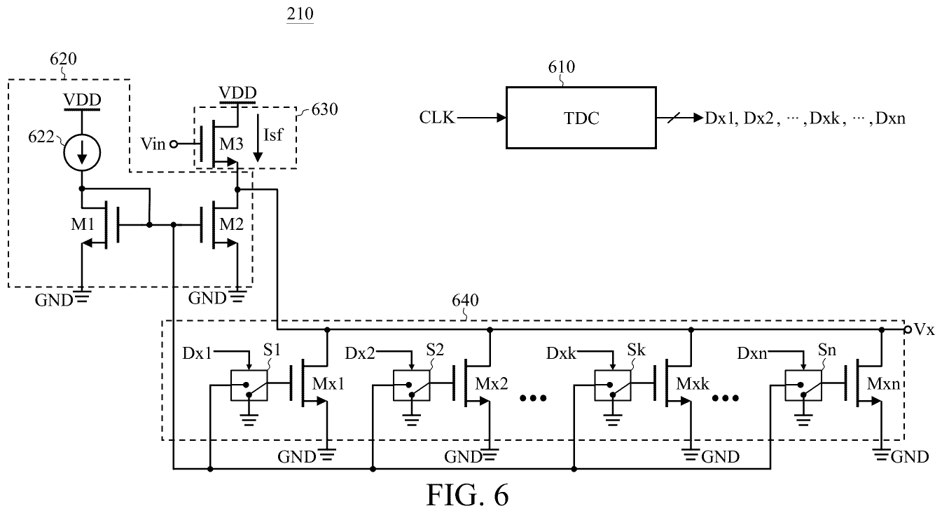

Reference is made to FIG. 6, which is a circuit diagram of the buffer circuit according to an embodiment of the present invention. The buffer circuit 210 includes a time-to-digital converter (TDC) 610, a current mirror 620, a source follower 630, and a transistor array 640. The TDC 610 is used to convert the operating clock CLK into a digital signal with n bits (including the bits Dx1, Dx2, Dxk, . . . , and Dxn, where n>=1). The current mirror 620 includes a current source 622, a transistor M1, and a transistor M2. The current mirror 620 provides the current Isf based on the current value of the current source 622, and the current Isf flows through the source follower 630. The source follower 630 includes a transistor M3. The source of the transistor M3 is coupled or electrically connected to the current mirror 620, the drain of the transistor M3 is coupled or electrically connected to a power supply voltage VDD, and the gate of the transistor M3 receives the input signal Vin. The source of the transistor M3 (i.e., the output terminal of the buffer circuit 210) outputs the intermediate voltage Vx.

The transistor array 640 includes multiple transistors (Mx1, Mx2, . . . , Mxk, . . . , Mxn) which are connected in parallel. The drain of each transistor is coupled or electrically connected to the source of the transistor M3. The source of each transistor is coupled or electrically connected to a reference voltage GND (e.g., ground). The gate of each transistor is coupled or electrically connected to a switch (S1, S2, . . . , Sk, . . . , Sn). Each switch Sk is controlled by the corresponding bit Dxk to couple or electrically connect the gate of the corresponding transistor Mxk (1<=k<=n) to the reference voltage GND (e.g., when Dxk=0) or to the gate of the transistor M2 (e.g., when Dxk=1).

People having ordinary skill in the art can understand from FIG. 6 that the magnitude of the current Isf is proportional to the digital signal (Dx1 to Dxn), which is also proportional to the operating clock CLK. In other words, the transistor array 640 adjusts the current Isf flowing through the transistor M3 according to the digital signal. In some embodiments, when the duty cycle of the operating clock CLK is greater (smaller), the current Isf is smaller (greater); that is, the duty cycle of the operating clock CLK is inversely proportional to the magnitude of the current Isf. In other words, when the sampling time Ts increases (the duty cycle of the operating clock CLK becomes greater), the buffer circuit 210 has more time to track the input signal Vin. Therefore, the current Isf is decreased to save power. When the sampling time Ts decreases (the duty cycle of the operating clock CLK becomes smaller), the buffer circuit 210 needs to catch up with the input signal Vin in a shorter time. Therefore, the current Isf is increased to enhance the signal tracking capability of the buffer circuit 210.

In some embodiments, the gain of the TDC 610 is a negative value, that is to say, when the duty cycle of the operating clock CLK is greater (smaller), the value of the digital signal outputted by the TDC 610 is smaller (greater).

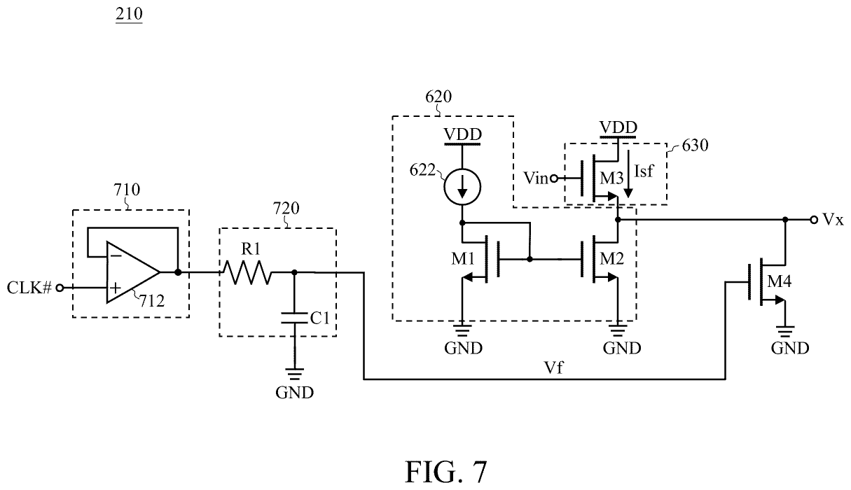

Reference is made to FIG. 7, which is a circuit diagram of the buffer circuit according to another embodiment of the present invention. The buffer circuit 210 includes a buffer unit 710, a low-pass filter (LPF) 720, the current mirror 620, the source follower 630, and a transistor M4 (e.g., an N-channel Metal-Oxide-Semiconductor Field-Effect Transistor, hereinafter referred to as the NMOS transistor). The buffer unit 710 has the function of signal isolation and can be embodied by an operational amplifier 712. The LPF 720, which is coupled to the buffer unit 710 and includes the resistor R1 and the capacitor C1, is used to low-pass filter the inverted signal CLK# of the operating clock CLK to generate the voltage Vf. The source of the transistor M4 is coupled or electrically connected to the reference voltage GND, the drain of the transistor M4 is coupled or electrically connected to the source of the transistor M3, and the gate of the transistor M4 is coupled or electrically connected to the LPF 720 to receive the voltage Vf.

The transistor M4 adjusts the current Isf according to the voltage Vf. More specifically, the greater the duty cycle of the operating clock CLK (i.e., the longer the sampling time Ts), the smaller the voltage Vf (because the LPF 720 filters the inverted signal CLK# of the operating clock CLK), causing the current Isf to become smaller (because the transistor M4 is conducted to a lower degree), thereby saving power. On the contrary, the smaller the duty cycle of the operating clock CLK (i.e., the shorter the sampling time Ts), the greater the voltage Vf, causing the current Isf to become greater (because the transistor M4 is conducted to a greater degree), thereby improving the signal tracking capability of the buffer circuit 210.

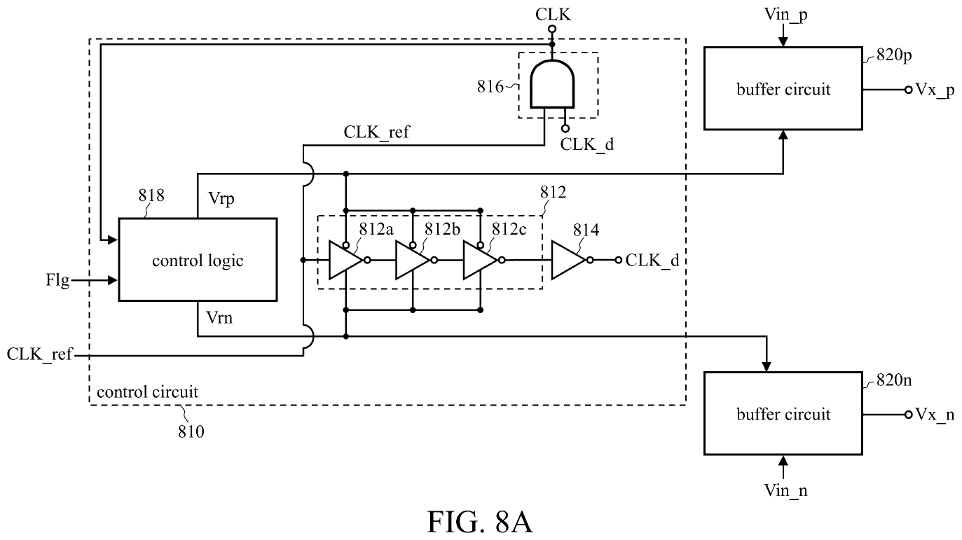

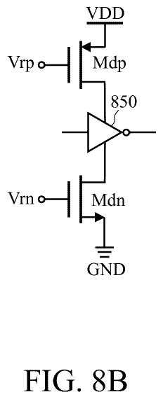

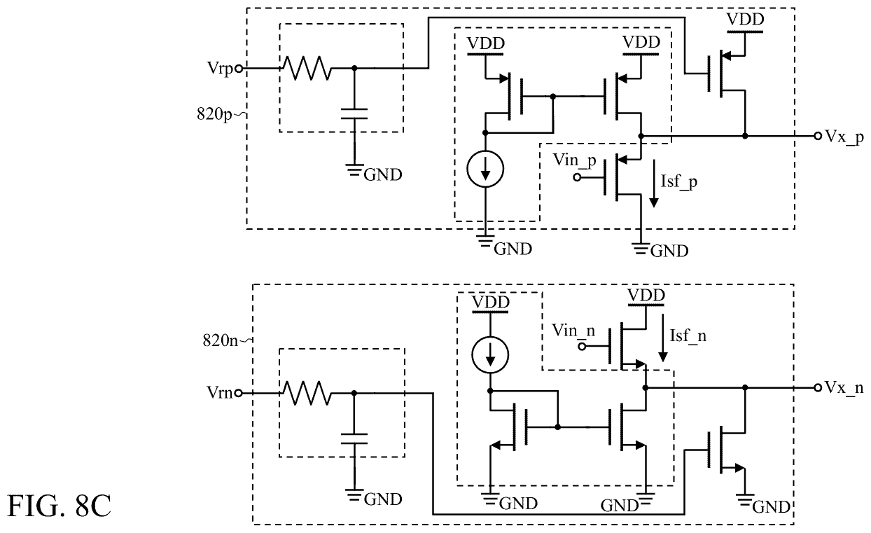

Reference is made to FIG. 8A, FIG. 8B, and FIG. 8C. FIG. 8A is a circuit diagram of the control circuit and the buffer circuit according to another embodiment of the present invention. FIG. 8B is a circuit diagram of the delay units in FIG. 8A. FIG. 8C shows the internal circuit of the buffer circuit. The circuit in FIG. 8A is suitable for differential signals, with the input signal Vin_p and the input signal Vin_n forming a differential signal pair. The control circuit 810 includes a delay circuit 812, an inverter 814, a logic circuit 816, and control logic 818.

The control circuit 810 first generates a delay control signal Vrp and a delay control signal Vrn based on the current operating clock CLK and the indication signal Flg. Then, the control circuit 810 delays the reference clock CLK_ref according to the delay control signal Vrp and the delay control signal Vrn to generate the adjusted operating clock CLK.

The buffer circuit 820p and the buffer circuit 820n are coupled or electrically connected to the control circuit 810. The buffer circuit 820p generates the intermediate voltage Vx_p according to the delay control signal Vrp and the input signal Vin_p, and the buffer circuit 820n generates the intermediate voltage Vx_n according to the delay control signal Vrn and the input signal Vin_n.

The delay circuit 812 delays the reference clock CLK_ref according to the delay control signal Vrp and the delay control signal Vrn. The delayed signal is inverted by the inverter 814 to generate the delayed clock CLK_d. The delay circuit 812 includes a delay unit 812a, a delay unit 812b, and a delay unit 812c. Each delay unit can be embodied by the circuit of FIG. 8B. As shown in FIG. 8B, a delay unit includes a transistor Mdp, a transistor Mdn, and an inverter 850. The source of the transistor Mdp is coupled or electrically connected to the power supply voltage VDD, the gate of the transistor Mdp receives the delay control signal Vrp, and the drain of the transistor Mdp is coupled or electrically connected to the inverter 850. The drain of the transistor Mdn is coupled or electrically connected to the inverter 850, the gate of the transistor Mdn receives the delay control signal Vrn, and the source of the transistor Mdn is coupled or electrically connected to the reference voltage GND. When the delay control signal Vrp is greater (smaller) and/or the delay control signal Vrn is smaller (greater), the delay time of the delay unit is longer.

Continuing with FIG. 8A, the logic circuit 816 performs operations on the reference clock CLK_ref and the delayed clock CLK_d to generate the operating clock CLK. When the delay time of the delay circuit 812 is longer, the duty cycle of the operating clock CLK is greater. In some embodiments, the logic circuit 816 can be embodied by an AND gate.

The control logic 818 generates the delay control signal Vrp and the delay control signal Vrn based on the operating clock CLK and the indication signal Flg. More specifically, when the conversion time Tc is sufficient (i.e., the duty cycle of the operating clock CLK is about to be increased, as in the example of FIG. 4), the control logic 818 raises the delay control signal Vrp and/or lowers the delay control signal Vrn to control the delay circuit 812 to delay the reference clock CLK_ref for a longer duration. Conversely, when the conversion time Tc is insufficient (i.e., the duty cycle of the operating clock CLK is about to be decreased, as in the example of FIG. 5), the control logic 818 lowers the delay control signal Vrp and/or raises the delay control signal Vrn to control the delay circuit 812 to delay the reference clock CLK ref for a shorter duration.

The delay control signal Vrp and the delay control signal Vrn can also be used to control the buffer circuit 820p and the buffer circuit 820n, respectively. Reference is made to FIG. 8C. The buffer circuit 820n is substantially the same as the buffer circuit 210 in FIG. 7, and the buffer circuit 820p replaces the NMOS transistors in the buffer circuit 210 with P-channel Metal-Oxide-Semiconductor Field-Effect Transistors (hereinafter referred to as PMOS transistors). It should be noted that, in the embodiment of FIG. 8C, the buffer unit 710 in FIG. 7 can be omitted. People having ordinary skill in the art can understand the operational details of the buffer circuit 820p and the buffer circuit 820n based on the discussion of FIG. 7. When the delay control signal Vrp becomes greater and/or the delay control signal Vrn becomes smaller (i.e., the duty cycle of the operating clock CLK becomes greater), the current Isf_p and/or the current Isf_n become smaller to save power. When the delay control signal Vrp becomes smaller and/or the delay control signal Vrn becomes greater (i.e., the duty cycle of the operating clock CLK becomes smaller), the current Isf_p and/or the current Isf_n become greater to improve the signal tracking capability of the buffer circuit 820p and the buffer circuit 820n.

In summary, the analog-to-digital conversion circuit 200 of the present invention can dynamically adjust the duty cycle of the operating clock CLK to enhance performance (including, but not limited to, improving linearity) and/or save power. The ADC 220 of the analog-to-digital conversion circuit 200 may be various forms of ADCs (including, but not limited to, a successive-approximation register (SAR) ADC). The technical features discussed above can be implemented in a time-interleaved ADC (TIADC).

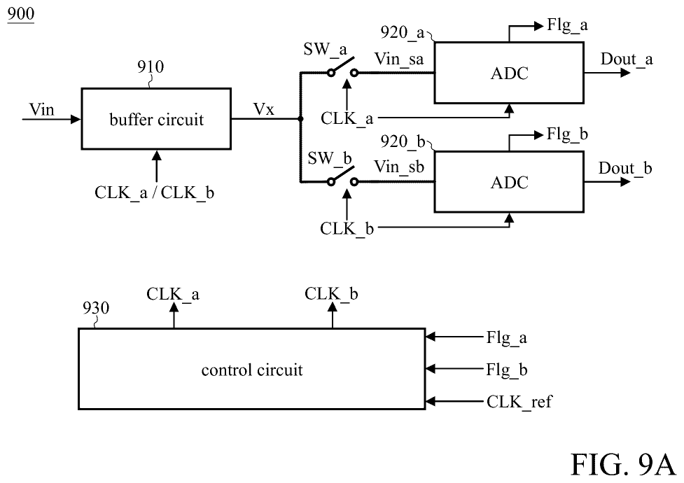

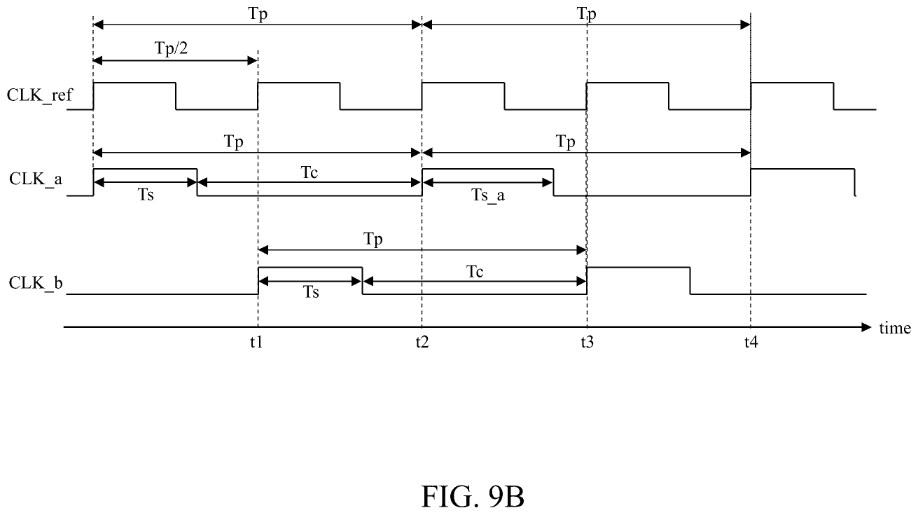

Reference is made to FIG. 9A and FIG. 9B. FIG. 9A is a functional block diagram of a TIADC according to an embodiment of the present invention, and FIG. 9B illustrates the clocks corresponding to FIG. 9A. The time-interleaved analog-to-digital conversion circuit 900 includes a buffer circuit 910, a sampling switch SW_a, a sampling switch SW_b, an ADC 920_a, an ADC 920_b, and a control circuit 930. The sampling switch SW_a and the sampling switch SW_b sample the intermediate voltage Vx according to the operating clock CLK_a and the operating clock CLK_b, respectively, to generate the voltage Vin_sa and the voltage Vin_sb. The ADC 920_a and the ADC 920_b perform analog-to-digital conversion on the voltage Vin_sa and the voltage Vin_sb according to the operating clock CLK_a and the operating clock CLK_b, respectively, to generate the digital signal Dout_a and the digital signal Dout_b, and respectively generate the indication signal Flg_a and the indication signal Flg_b after an analog-to-digital conversion is completed The control circuit 930 is coupled to the buffer circuit 910, the sampling switch SW_a, the sampling switch SW_b, the ADC 920_a, and the ADC 920_b.

Reference is made to FIG. 9B. The period of the reference clock CLK_ref (Tp/2) is the operating cycle of the time-interleaved analog-to-digital conversion circuit 900, and the periods of the operating clock CLK_a and the operating clock CLK_b are both Tp. Similar to the control circuit 230, the control circuit 930 generates the operating clock CLK_a based on the indication signal Flg_a and the reference clock CLK_ref, and generates the operating clock CLK_b based on the indication signal Flg_b and the reference clock CLK_ref. More specifically, as discussed in FIG. 3 to FIG. 5, the control circuit 930 generates a first control signal based on the operating clock CLK_a and the indication signal Flg_a, and then adjusts the duty cycle of the operating clock CLK_a based on the first control signal and the reference clock CLK_ref. Similarly, the control circuit 930 generates the second control signal based on the operating clock CLK_b and the indication signal Flg_b, and then adjusts the duty cycle of the operating clock CLK_b according to the second control signal and the reference clock CLK ref.

After the time-interleaved analog-to-digital conversion circuit 900 operates for a period of time, the duty cycle of the operating clock CLK_a may not be equal to the duty cycle of the operating clock CLK_b. For example, the duty cycle (Ts_a/Tp) of the operating clock CLK_a between the time point t2 and the time point t4 is different from the duty cycle (Ts/Tp) of the operating clock CLK_b between the time point t1 and the time point t3 (because Ts_a>Ts).

Similar to the buffer circuit 210, the buffer circuit 910 can adjust the current according to the operating clock CLK_a or the operating clock CLK_b to save power or improve signal tracking capability.

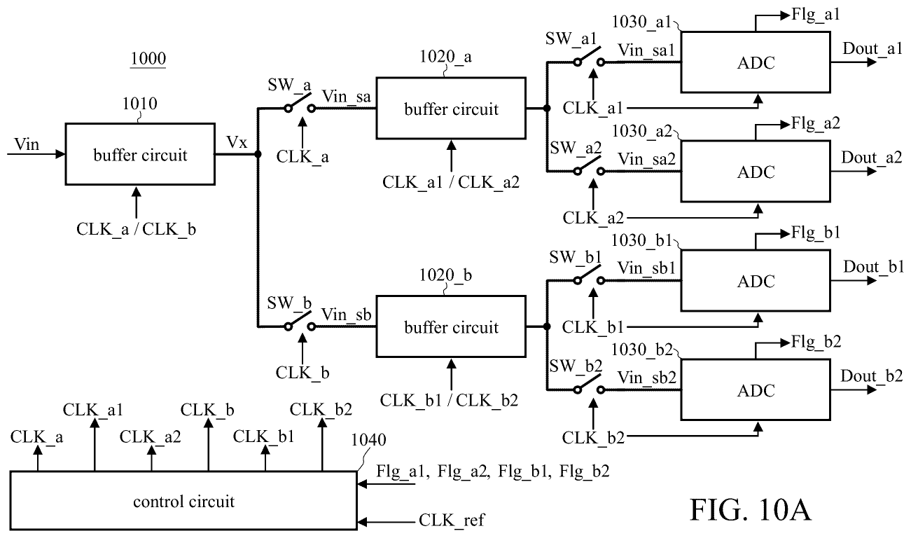

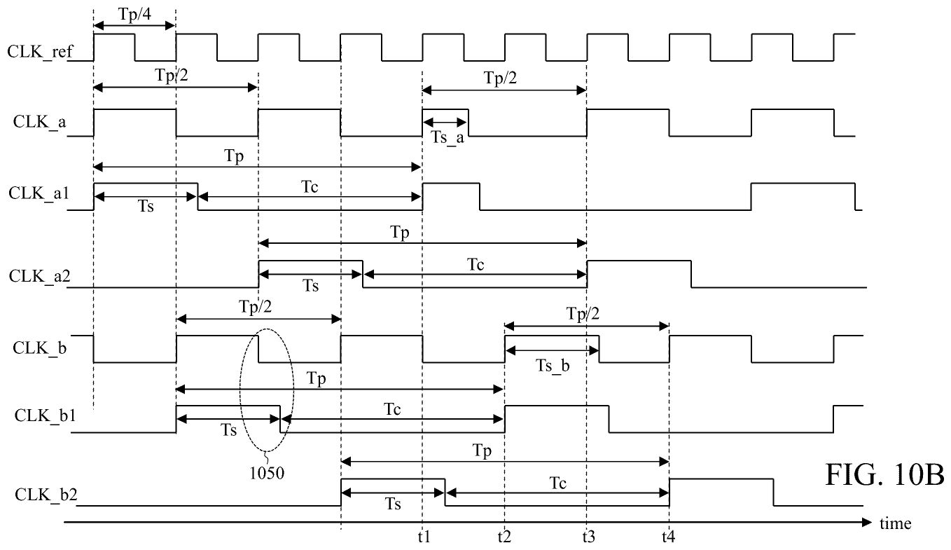

Reference is made to FIG. 10A and FIG. 10B. FIG. 10A is a functional block diagram of a time-interleaved ADC according to another embodiment of the present invention, and FIG. 10B illustrates the clocks corresponding to FIG. 10A. The time-interleaved analog-to-digital conversion circuit 1000 includes a buffer circuit 1010, a buffer circuit 1020_a, a buffer circuit 1020_b, an ADC 1030_a1, an ADC 1030_a2, an ADC 1030_b1, an ADC 1030_b2, a sampling switch SW_a, a sampling switch SW_b, a sampling switch SW_a1, a sampling switch SW_a2, a sampling switch SW_b1, a sampling switch SW_b2, and a control circuit 1040.

The sampling switches SW_a, SW_b, SW_a1, SW_a2, SW_b1, and SW_b2 operate according to the operating clocks CLK_a, CLK_b, CLK_a1, CLK_a2, CLK_b1, and CLK_b2, respectively, to generate the voltages Vin_sa, Vin_sb, Vin_sa1, Vin_sa2, Vin_sb1, and Vin_sb2, respectively. The ADCs 1030_a1, 1030_a2, 1030_b1, and 1030_b2 operate according to the operating clocks CLK_a1, CLK_a2, CLK_b1, and CLK_b2, respectively, to convert the voltages Vin_sa1, Vin_sa2, Vin_sb1, and Vin_sb2 into the digital signals Dout_a1, Dout_a2, Dout_b1, and Dout_b2, respectively, and generate the indication signals Flg_a1, Flg_a2, Flg_b1, and Flg_b2, respectively.

The control circuit 1040 generates the operating clock CLK_a1 based on the reference clock CLK_ref and the indication signal Flg_a1, generates the operating clock CLK_a2 based on the reference clock CLK_ref and the indication signal Flg_a2, generates the operating clock CLK_b1 based on the reference clock CLK ref and the indication signal Flg_b1, and generates the operating clock CLK_b2 based on the reference clock CLK_ref and the indication signal Flg_b2.

The time-interleaved analog-to-digital conversion circuit 1000 is an M*N architecture. In the example of FIG. 10A, M=N=2; however, this is for illustrative purposes only.

Reference is made to FIG. 10B. The period (Tp/4) of the reference clock CLK ref is the operating cycle of the time-interleaved analog-to-digital conversion circuit 1000. The periods of the operating clocks CLK_a and CLK_b are both Tp/2, while the periods of the operating clocks CLK_a1, CLK_a2, CLK_b1, and CLK_b2 are all Tp.

It should be noted that because the sampling switch SW_a1 (or SW_b1) and the sampling switch SW_a2 (or SW_b2) cannot be turned off until the sampling switch SW_a(or SW_b) is turned off (as shown in the circled area 1050 in the figure), the falling edges of the operating clock CLK_a1 (or CLK_b1) and the operating clock CLK_a2 (or CLK_b2) cannot be earlier than the falling edge of the operating clock CLK_a (or CLK_b). In other words, the control circuit 1040 further adjusts the duty cycle of the operating clock CLK_a (or CLK_b) according to the duty cycles of the operating clock CLK_a1 (or CLK_b1) and the operating clock CLK_a2 (or CLK_b2). For example, if the sampling time Ts of the operating clock CLK_a1 is shortened to less than Tp/4, then the duty cycle of the operating clock CLK_a must be less than 50%.

After the time-interleaved analog-to-digital conversion circuit 1000 operates for a period of time, the duty cycle of the operating clock CLK_a may not be equal to the duty cycle of the operating clock CLK_b. For example, the duty cycle of the operating clock CLK_a between the time point t1 and the time point t3 (2Ts_a/Tp) is different from the duty cycle of the operating clock CLK_b between the time point t2 and the time point t4 (2Ts_b/Tp) (because Ts_a<Ts_b).

Similar to the buffer circuit 210, the buffer circuit 1020_a (1020_b) can adjust the current according to the operating clock CLK_a1 (CLK_b1) or the operating clock CLK_a2 (CLK_b2) to save power or improve signal tracking capability. Similarly, the buffer circuit 1010 can adjust the current according to the operating clock CLK_a or the operating clock CLK_b to save power or improve signal tracking capability.

The buffer circuits 910, 1010, 1020_a, and 1020_b can be embodied by the buffer circuit of FIG. 6 or FIG. 7. In other embodiments, when processing differential signals, the control circuit 930 and the buffer circuit 910 in FIG. 9A, as well as the control circuit 1040 and the buffer circuit 1010 (1020_a or 1020_b) in FIG. 10A, can be embodied by the circuits of FIGS. 8A to 8C.

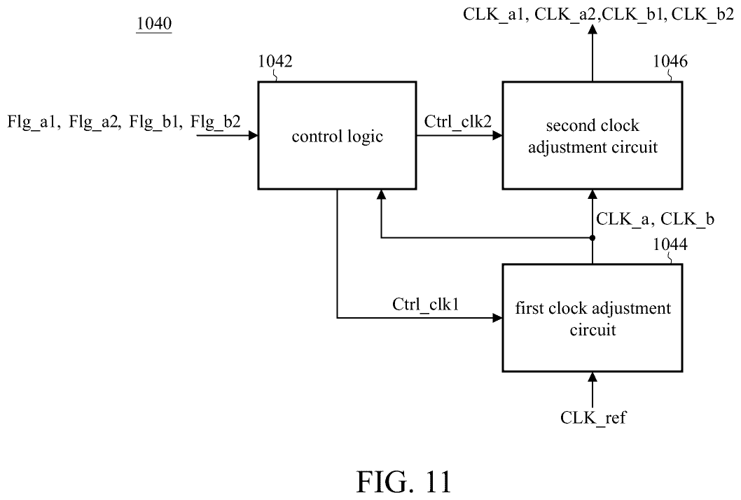

Reference is made to FIG. 11, which is a functional block diagram of the control circuit according to another embodiment of the present invention. The control circuit 1040 includes control logic 1042, a first clock adjustment circuit 1044, and a second clock adjustment circuit 1046. The control logic 1042 generates the first clock adjustment signal Ctrl_clk1 and the second clock adjustment signal Ctrl_clk2 based on the indication signals Flg_a1, Flg_a2, Flg_b1, and Flg_b2, and the operating clocks CLK_a and CLK_b. The first clock adjustment circuit 1044 is coupled to the control logic 1042 and used to generate the operating clocks CLK_a and CLK_b based on the first clock adjustment signal Ctrl_clk1 and the reference clock CLK ref. The second clock adjustment circuit 1046 is coupled to the control logic 1042 and the first clock adjustment circuit 1044 and used to generate the operating clocks CLK_a1, CLK_a2, CLK_b1, and CLK_b2 based on the second clock adjustment signal Ctrl_clk2 and the operating clocks CLK_a and CLK_b. Similarly, in some embodiments, the first clock adjustment circuit 1044 and the second clock adjustment circuit 1046 can be embodied by a phase interpolation circuit and/or a delay circuit.

It should be noted that the number of ADCs in FIG. 9A and FIG. 10A is for illustration purposes only and not intended to limit the present invention.

Note that the shape, size, and ratio of any element in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. An analog-to-digital conversion circuit configured to convert an input signal into a digital signal, comprising:
a buffer circuit configured to receive the input signal and generate an intermediate voltage;
a switch coupled to the buffer circuit and configured to sample the intermediate voltage according to an operating clock to generate a voltage;
an analog-to-digital converter (ADC) coupled to the switch and configured to convert the voltage into the digital signal according to the operating clock and generate an indication signal; and
a control circuit coupled to the switch and the ADC and configured to adjust a duty cycle of the operating clock according to the indication signal and a reference clock;
wherein the indication signal indicates that the ADC has completed an analog-to-digital conversion operation.

2. The analog-to-digital conversion circuit of claim 1, wherein the digital signal is a first digital signal, and the buffer circuit further receives the operating clock and comprises:
a time-to-digital converter configured to generate a second digital signal according to the operating clock;
a current mirror;
a source follower coupled to the current mirror and configured to receive the input signal and provide the intermediate voltage; and
a transistor array coupled to the current mirror;
wherein the transistor array adjusts a current flowing through the source follower according to the second digital signal.

3. The analog-to-digital conversion circuit of claim 2, wherein the duty cycle of the operating clock is inversely proportional to magnitude of the current.

4. The analog-to-digital conversion circuit of claim 2, wherein the transistor array comprises a plurality of transistors connected in parallel, and each of the plurality of transistors is controlled by one bit of the second digital signal.

5. The analog-to-digital conversion circuit of claim 2, wherein the source follower is a transistor, a first terminal of the transistor is coupled to a power supply voltage, a second terminal of the transistor receives the input signal, a third terminal of the transistor is an output terminal of the buffer circuit, and the third terminal is coupled to the current mirror and the transistor array.

6. The analog-to-digital conversion circuit of claim 1, wherein the voltage is a first voltage, and the buffer circuit further receives the operating clock and comprises:
a low-pass filter (LPF) configured to low-pass filter an inverted signal of the operating clock to generate a second voltage;
a current mirror;
a source follower coupled to the current mirror and configured to receive the input signal and provide the intermediate voltage; and
a transistor, wherein a first terminal of the transistor is coupled to the current mirror and the source follower, a second terminal of the transistor receives the second voltage, and a third terminal of the transistor is coupled to a reference voltage;
wherein the transistor regulates a current flowing through the source follower according to the second voltage.

7. The analog-to-digital conversion circuit of claim 6, wherein the duty cycle of the operating clock is inversely proportional to magnitude of the current.

8. The analog-to-digital conversion circuit of claim 6, wherein the transistor is an N-channel Metal-Oxide-Semiconductor Field-Effect Transistor, and the duty cycle of the operating clock is inversely proportional to the second voltage.

9. The analog-to-digital conversion circuit of claim 6, wherein the transistor is a first transistor, the source follower is a second transistor, a fourth terminal of the second transistor is coupled to a power supply voltage, a fifth terminal of the second transistor receives the input signal, a sixth terminal of the second transistor is an output terminal of the buffer circuit, and the sixth terminal is coupled to the current mirror and the first transistor.

10. The analog-to-digital conversion circuit of claim 1, wherein the control circuit comprises:
control logic configured to generate a first delay control signal and a second delay control signal according to the indication signal and the operating clock;
a delay circuit coupled to the control logic and configured to delay the reference clock according to the first delay control signal and the second delay control signal to generate a delayed clock; and
a logic circuit coupled to the control logic and the delay circuit and configured to generate the operating clock according to the reference clock and the delayed clock.

11. The analog-to-digital conversion circuit of claim 10, wherein the voltage is a first voltage, and the buffer circuit comprises:
a low-pass filter (LPF) configured to low-pass filter one of the first delay control signal and the second delay control signal to generate a second voltage;
a current mirror;
a source follower coupled to the current mirror and configured to receive the input signal and provide the intermediate voltage; and
a transistor, wherein a first terminal of the transistor is coupled to the current mirror and the source follower, a second terminal of the transistor receives the second voltage, and a third terminal of the transistor is coupled to a reference voltage;
wherein the transistor regulates a current flowing through the source follower according to the second voltage.

12. The analog-to-digital conversion circuit of claim 1, wherein the ADC is a first ADC, the switch is a first switch, the operating clock is a first operating clock, the voltage is a first voltage, the digital signal is a first digital signal, the indication signal is a first indication signal, and the analog-to-digital conversion circuit further comprises:
a second switch coupled to the buffer circuit and configured to sample the intermediate voltage according to a second operating clock to generate a second voltage; and
a second ADC coupled to the second switch and configured to convert the second voltage into a second digital signal according to the second operating clock and generate a second indication signal;
wherein the control circuit generates the first operating clock and the second operating clock according to the first indication signal, the second indication signal, and the reference clock.

13. The analog-to-digital conversion circuit of claim 12, wherein a duty cycle of the first operating clock is not equal to a duty cycle of the second operating clock.

14. A time-interleaved analog-to-digital conversion circuit configured to convert an input signal into a digital signal and comprising:
a first buffer circuit configured to receive the input signal and generate an intermediate voltage;
a first switch coupled to the first buffer circuit and configured to sample the intermediate voltage according to a first operating clock to generate a first voltage;
a second switch coupled to the first buffer circuit and configured to sample the intermediate voltage according to a second operating clock to generate a second voltage;
a second buffer circuit coupled to the first switch;
a third buffer circuit coupled to the second switch;
a first analog-to-digital converter (ADC) coupled to the second buffer circuit and configured to operate according to a third operating clock and generate a first indication signal;
a second ADC coupled to the second buffer circuit and configured to operate according to a fourth operating clock and generate a second indication signal;
a third ADC coupled to the third buffer circuit and configured to operate according to a fifth operating clock and generate a third indication signal;
a fourth ADC coupled to the third buffer circuit and configured to operate according to a sixth operating clock and generate a fourth indication signal; and
a control circuit coupled to the first switch, the second switch, the first ADC, the second ADC, the third ADC, and the fourth ADC, and configured to adjust at least one of duty cycles of the first operating clock, the second operating clock, the third operating clock, the fourth operating clock, the fifth operating clock, and the sixth operating clock according to the first indication signal, the second indication signal, the third indication signal, the fourth indication signal, and a reference clock;
wherein the first indication signal, the second indication signal, the third indication signal, and the fourth indication signal respectively indicate that an analog-to-digital conversion operation of the first ADC, the second ADC, the third ADC, and the fourth ADC has been completed.

15. The time-interleaved analog-to-digital conversion circuit of claim 14, wherein the first buffer circuit adjusts an internal current of the first buffer circuit according to at least one of the first operating clock and the second operating clock.

16. The time-interleaved analog-to-digital conversion circuit of claim 15, wherein the second buffer circuit adjusts an internal current of the second buffer circuit according to at least one of the third operating clock and the fourth operating clock.

17. The time-interleaved analog-to-digital conversion circuit of claim 16, wherein the control circuit adjusts a duty cycle of the first operating clock according to the third operating clock and the fourth operating clock.

18. The time-interleaved analog-to-digital conversion circuit of claim 14, wherein the second buffer circuit adjusts its internal current according to at least one of the third operating clock and the fourth operating clock.

19. The time-interleaved analog-to-digital conversion circuit of claim 14, wherein the control circuit comprises:
control logic configured to generate a first clock adjustment signal and a second clock adjustment signal according to the first indication signal, the second indication signal, the third indication signal, the fourth indication signal, the first operating clock, and the second operating clock;
a first clock adjustment circuit coupled to the control logic and configured to generate the first operating clock and the second operating clock according to the first clock adjustment signal and the reference clock; and
a second clock adjustment circuit coupled to the control logic and the first clock adjustment circuit and configured to generate the third operating clock, the fourth operating clock, the fifth operating clock, and the sixth operating clock according to the second clock adjustment signal, the first operating clock, and the second operating clock.
